(19) United States
(12) Patent Application Publication
(10) Pub. No.: US 2015/0373864 A1
(43) Pub. Date: Dec. 24, 2015

(54) DISPLAY APPARATUS AND METHOD OF MANUFACTURING SAME

(71) Applicant: Samsung Display Co., Ltd., Yongin-city (KR)

(72) Inventor: Tai-Yun JUNG, Yongin-city (KR)

(21) Appl. No.: 14/526,260

(22) Filed: Oct. 28, 2014

(30) Foreign Application Priority Data
Jun. 19, 2014 (KR) 10-2014-0075052

(51) Int. Cl. H05K 5/02; H05K 13/00; H05K 1/02

(52) U.S. Cl. CPC H05K 5/0217; H05K 1/028; H05K 13/0023; H05K 2201/10128; H05K 2201/05

(57) ABSTRACT

A display apparatus includes a flexible display panel and a support mold including an accommodation space. A width of the accommodation space is smaller than a width of the flexible display panel. The support mold is configured to support the flexible display panel in a bent state in the accommodation space.

### CROSS-REFERENCE TO RELATED APPLICATION

This application claims priority from and the benefit of Korean Patent Application No. 10-2014-0075052, filed on Jun. 19, 2014, which is hereby incorporated by reference for all purposes as if fully set forth herein.

### BACKGROUND

1. Field

Exemplary embodiments relate to a display apparatus, such as a TV, and a method of manufacturing the same.

2. Discussion of the Background

In a display apparatus using a flat panel, such as an organic light-emitting display (OLED) panel, the OLED panel is flexible, and thus, the OLED panel may be bent such that a curvature thereof is appropriate for the display apparatus, such as, for viewing pleasure.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments include a display apparatus, such as a TV, and a method of manufacturing the same.

Additional aspects will be set forth in part in the description which follows and, in part, will be apparent from the description, or may be learned by practice of the presented embodiments.

According to exemplary embodiments disclose, a display apparatus includes: a flexible display panel; and a support mold comprising an opening to an accommodation space, wherein a width of the accommodation space is smaller than a width of the flexible display panel, and wherein the support mold is configured to support the flexible display panel in a bent state in the accommodation space.

According to exemplary embodiments also disclose, a method of manufacturing a display apparatus includes: forming a flexible display panel; forming a support mold including an opening to an accommodation space, a width of the accommodation space being less than a width of the flexible display panel; and inserting the flexible display panel into the accommodation space, wherein, with respect to the opening, the flexible display panel is concavely bent in the accommodation space.

The foregoing general description and the following detailed description are exemplary and explanatory and are intended to provide further explanation of the claimed subject matter

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1A is a top view of a display apparatus according to exemplary embodiments.

FIG. 1B is a cross-sectional view taken along line A-A of FIG. 1A, according to exemplary embodiments.

FIG. 1C is a cross-sectional view of a modified example of the display apparatus of FIG. 1B, according to exemplary embodiments.

FIGS. 2A, 2B, 2C, 2D, and 2E are cross-sectional views sequentially illustrating the display apparatus of FIG. 1B at various stages of manufacture, according to exemplary embodiments.

FIG. 3A is a top view of a display apparatus, according to exemplary embodiments.

FIG. 3B is a cross-sectional view taken along line B-B of FIG. 3A, according to exemplary embodiments.

FIG. 3C is a magnified perspective view of a stop bracket engagement portion, according to exemplary embodiments.

FIG. 4A is a cross-sectional view of a display apparatus, according to exemplary embodiments.

FIG. 4B is a magnified perspective view of a hook bracket engagement portion, according to exemplary embodiments.

FIGS. 5A, 5B, and 5C are cross-sectional views of the display apparatus of FIG. 4A at various stages of manufacture, according to exemplary embodiments.

FIG. 6A is a top view of a display apparatus, according to exemplary embodiments.

FIG. 6B is a cross-sectional view taken along line C-C of FIG. 6A, according to exemplary embodiments.

FIG. 7 is a cross-sectional view of an internal structure of a flexible panel of a display apparatus, according to exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

When certain exemplary embodiments may be implemented differently, a process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

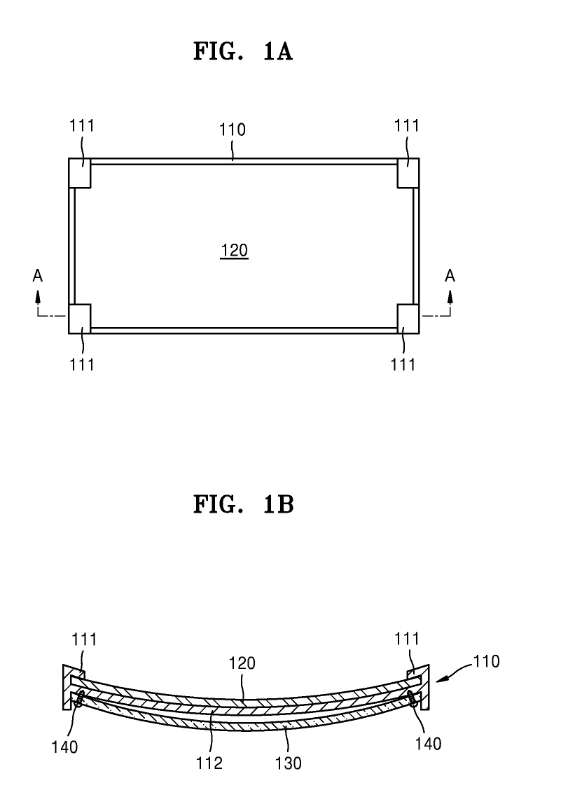

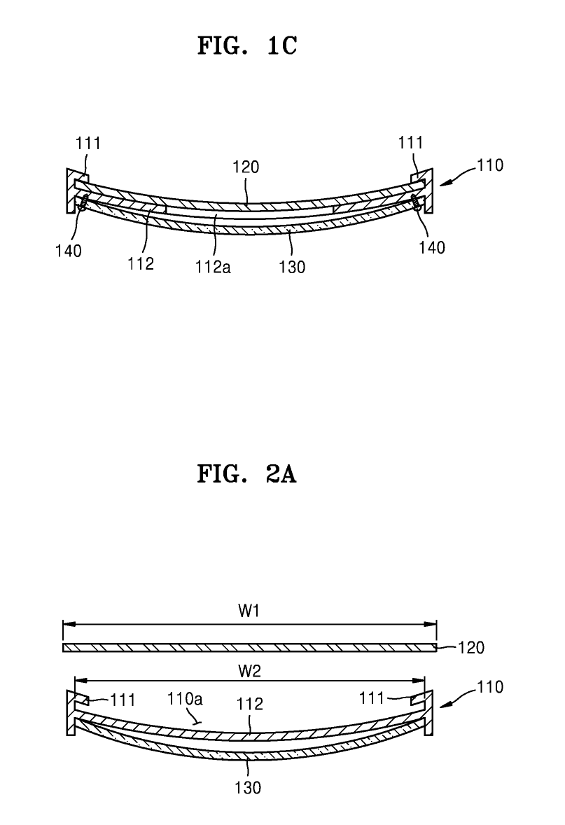

FIGS. 1A and 1B illustrate a display apparatus according to exemplary embodiments.

Referring to FIGS. 1A and 1B, the display apparatus has a structure in which a flexible panel 120 is supported by a support mold 110. The flexible panel 120 has a structure in which a thin-film transistor and a light-emitting diode for realizing an image, an encapsulating layer for covering and protecting the thin-film transistor and the light-emitting diode, and the like are stacked on a flexible substrate (not shown). Since the flexible substrate is used instead of a rigid glass substrate, the flexible panel 120 may be freely bendable within a range allowed by the flexibility of the flexible substrate. As shown in FIG. 1B, the flexible panel 120 may be bent such that the center thereof (or substantially the center) is concave. The flexible panel 120 is supported by the support mold 110 in a bent state in which the flexible panel 120 is concave at the center thereof when viewed from a front (or viewing) side of the flexible panel 120 (e.g., an upper side of the flexible panel 120 in FIG. 1B) on which an image is realized. The flexible panel 120 may include an organic light-emitting display (OLED) panel.

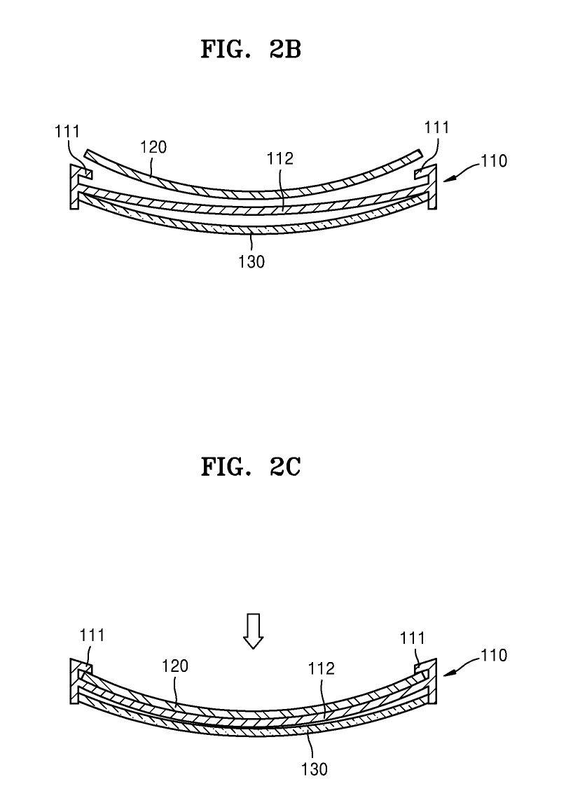

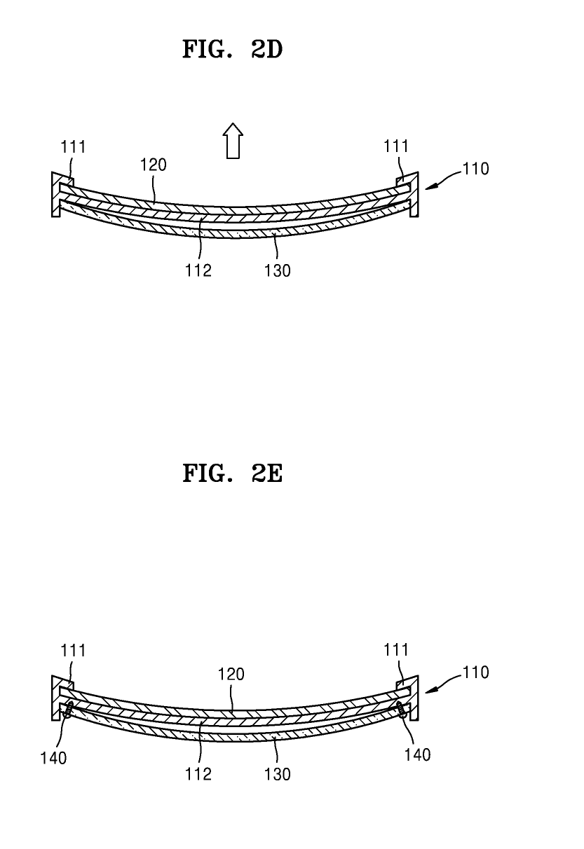

The support mold 110 may include a support body made of an elastically deformable material, such as polycarbonate, and may include a support rib 112 for forming an accommodation space (110a: refer to FIG. 2A) for the flexible panel 120, a stop protrusion 111, and the like. Referring to FIG. 2A, since a width W2 of the accommodation space 110a is narrower than a width W1 of the flexible panel 120 (W1>W2), when the flexible panel 120 is pushed into the accommodation space 110a, the flexible panel 120 naturally bends. The support rib 112 may support a rear side of the flexible panel 120 opposite to the front side, and the stop protrusion 111 may work as a stopper that interferes with the four corner portions of an edge of the flexible panel 120 and prevents the flexible panel 120 from being released towards the front side of the flexible panel 120.

Reference numeral 130 denotes a rear chassis of which one side is affixed to the support rib 112 of the support mold 110 by a fixing screw 140. It is contemplated, however, that any other coupling mechanism may be utilized in association with exemplary embodiments described herein. The rear chassis 130 is configured to protect a rear surface of the display apparatus from external shock, or the like, and is also configured to reduce the risk of the flexible panel 120 being released from large elastic movement of the support rib 112 after assembly, because the rear chassis is affixed to the support rib 112 of the support mold 110 as described above.

An exemplary method of manufacturing the display apparatus by affixing the flexible panel 120 to the support mold 110 will be described in detail below, and an internal structure of the flexible panel 120 will be described first.

Referring to FIG. 7, the flexible panel 120 includes a thin-film transistor 121 and an electroluminescent (EL) element 122. In more detail, a semiconductor active layer 121f is formed on a buffer layer 121a adjacent to a flexible substrate 123, and has source and drain regions doped with high-density N- or P-type impurities. The semiconductor active layer 121f may be formed of an oxide semiconductor; however, any other suitable material may be utilized in association with exemplary embodiments described herein. For example, the oxide semiconductor may include an oxide of a material including group 12, 13, and 14 metallic elements, such as zinc (Zn), indium (In), gallium (Ga), tin (Sn), cadmium (Cd), germanium (Ge), and Hafnium (Hf), and combinations thereof. For example, the semiconductor active layer 121f may include G-I-Z-O[(In₂O³)ₐ(Ga₂O₃)_{b}(ZnO)_{c}] (a, b, and c are real numbers which satisfy the conditions of a≧0, b≧0, and c>0, respectively). A gate electrode 121g is formed on the semiconductor active layer 121f by interposing a gate insulating layer 121b between the gate electrode 121g and the semiconductor active layer 121f. A source electrode 121h and a drain electrode 121i are formed on opposing sides of the gate electrode 121g. An inter-layer insulating layer 121c is provided between the gate electrode 121g and the source electrode 121h and between the gate electrode 121g and the drain electrode 121i. A passivation layer 121d is interposed between the source electrode 121h and an anode electrode 122a of the EL element 122 and between the drain electrode 121i and the anode electrode 122a.

An insulating planarization layer 121e including acryl or the like is formed on the anode electrode 122a, and the EL element 122 is formed in an aperture 122d in the planarization layer 121e.

The EL element 122 facilitates the display of image information by emitting red, green, and/or blue light depending on a current flow. The EL element 122 includes the anode electrode 122a, which is connected to the drain electrode 121i of the thin-film transistor 121 and receives positive power from the drain electrode 121i, a cathode electrode 122c, which covers the entire pixel and supplies negative power, and an emission layer 122b, which is disposed between the anode electrode 122a and the cathode electrode 122c and emits light.

A hole injection layer (HIL), a hole transport layer (HTL), an electron transport layer (ETL), an electron injection layer (EIL), and the like may be stacked adjacent to the emission layer 122b.

The emission layer 122b may be separately formed for each pixel, and pixels for emitting red, green, and blue light may be combined to form one unit pixel. The emission layer 122b may also be commonly formed over the entire pixel area regardless of locations of pixels. In this manner, the emission layer 122b may be formed by vertically stacking or mixing layers including luminescent materials, which emit red, green, and blue lights. The color combination is not limited to red, green, and blue, and may include other sets of color combination if the color combination may produce white color.

Although not illustrated, a color conversion layer for converting the emitted white color into another color, or a color filter may be further included. In addition, a thin-film encapsulation layer (not shown), which may includes an organic layer and an inorganic layer alternately stacked, may be formed on the cathode electrode 122c.

The flexible panel 120 having the above-described structure is bendable, and thus, the flexible panel 120 may be accommodated in the accommodation space 110a (refer to FIG. 2A) of the support mold 110 in a state in which the flexible panel 120 is bent such that the center of the flexible panel 120 is concave.

The display apparatus described above may be manufactured as shown in FIGS. 2A, 2B, 2C, 2D, and 2E. That is, FIGS. 2A, 2B, 2C, 2D, and 2E are cross-sectional views sequentially illustrating the display apparatus of FIG. 1B at various stages of manufacture, according to exemplary embodiments.

Referring to FIG. 2A, the flexible panel 120 and the support mold 110 are prepared. The accommodation space 110a is defined by the support rib 112, the stop protrusion 111, and the side walls of the support mold 110. The width W2 of the accommodation space 110a is narrower than the width W1 of the flexible panel 120 as described above. The rear chassis 130 is mounted on the rear surface of the support mold 110 and is supported between side walls of the support mold 110, which is not yet affixed to the support rib 112. The support rib 112 and the rear chassis 130 are both bent such that the respective centers thereof are concave.

Referring to FIG. 2B, when the flexible panel 120 is pushed from the front side of the support mold 110 into the accommodation space 110a, the flexible panel 120 may be inserted into the accommodation space 110a so that the flexible panel 120 is bent and the center thereof is concave.

Referring to FIG. 2C, while the flexible panel 120 is pushed into the accommodation space 110a, the support rib 112 is also bent in an entering direction of the flexible panel 120 such that the center of the support rib 112 is also concavely bent. When the flexible panel 120 is securely pushed into the accommodation space 110a, the support rib 112 will recover its original shape, as shown in FIG. 2D, and the flexible panel 120 is fully inserted into the accommodation space 110a. As such, the flexible panel 120 is bent with its center concave from the perspective of an observer viewing a display surface of the flexible panel 120.

Once the flexible panel 120 has been inserted into the accommodation space 110a of the support mold 110, the flexible panel 120 cannot be easily released to the outside. Since the stop protrusion 111 is configured to work as a stopper, the stop protrusion will interfere with a corner portion of an edge of the flexible panel 120 that prevents the flexible panel 120 from being released. The flexible panel 120 may be released if the flexible panel 120 can be bent in a direction such that the center thereof is convex toward the front side (i.e., in a direction opposite to that in which the flexible panel 120 bends when entering the accommodation space 110a). In order for the flexible panel 120, which has been bent so that the center of the flexible panel 120 is concave, to be bent to that the center of the flexible panel 120 is convex, the flexible panel 120 would need to be flattened in the accommodation space 110a during the release. However, since the width W2 of the accommodation space 110a is narrower than the width W1 of the flexible panel 120 as described above, the flexible panel 120 cannot be flattened. Therefore, the flexible panel 120 may not be easily released.

Referring to FIG. 2E, the rear chassis 130 and the support rib 112 may be affixed by the fixing screw 140. It is contemplated, however, that any other suitable coupling mechanism, whether mechanical, chemical, etc., may be utilized to fix (or otherwise couple) the rear chassis 130 to the support rib 112 may be utilized in association with exemplary embodiments described herein. By fixing one side of the support rib 112 to the rear chassis 130, the bending range of the support rib 112 may be controlled. As such, the elastic movement of the support rib 112 may be controlled from being bent back to the state as shown in FIG. 2C, and the possibility of the flexible panel 120 being released may be further reduced. If the support rib 112 is bent back to the state as shown in FIG. 2C, the flexible panel 120 may also be bent back to the position when entering the accommodation space 110a. Thus, the possibility of the flexible panel 120 being released is may be reduced by controlling the elastic bending range of the support rib 112 once the flexible panel 120 has been inserted into the accommodation space 110a.

As described above, the flexible panel 120 may be supported by the support mold 110 and the rear chassis 130. Since a separate front chassis is not utilized to support the flexible panel 120 from being released towards the front side thereof, the display apparatus may be manufactured relatively thinner than a conventional display apparatus. If a display apparatus includes a separate front chassis for fully covering and blocking a front of the flexible panel 120, the display apparatus may be much thicker and heavier. However, since exemplary embodiment may provide support for the flexible panel 120 from being released towards the front side with the support mold 110 free of a separate front chassis for fully covering and blocking a front of the flexible panel 120, the display apparatus may be manufactured relatively thinner and lighter weight than a conventional display apparatus.

Referring back to FIG. 1B, the support rib 112 supports the entire rear surface of the flexible panel 120. However, exemplary embodiments are not limited thereto, and a modified structure may be employed, such as shown in FIG. 1C, in which a hole 112a is formed in, for example, the middle of the support rib 112.

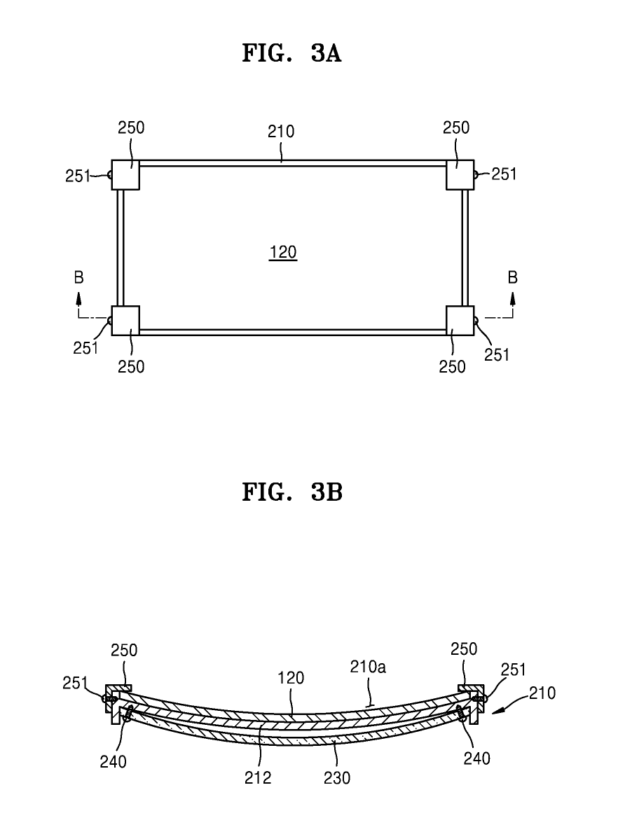

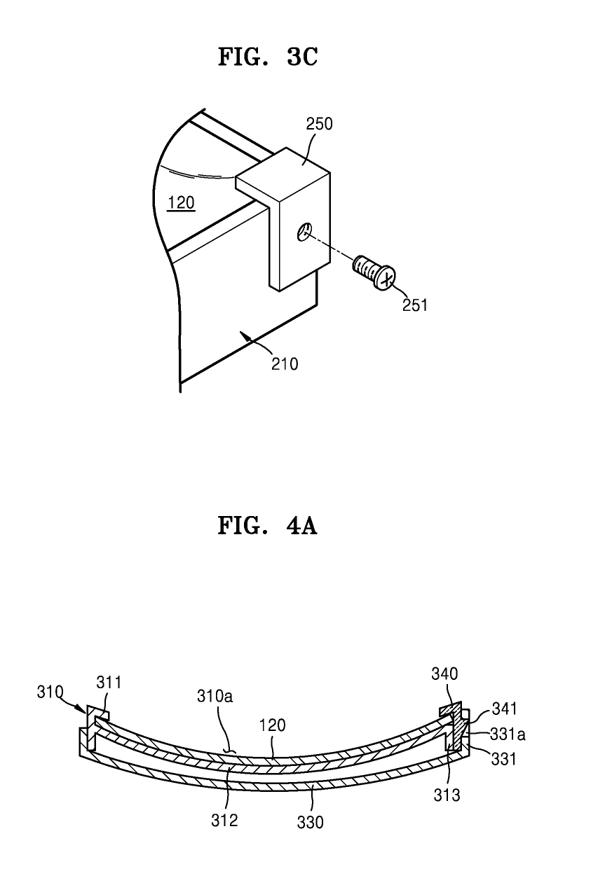

FIGS. 3A, 3B, and 3C illustrate a display apparatus according to exemplary embodiments.

As seen in FIGS. 3A, 3B, and 3C, the display apparatus may also include a support mold 210 for supporting the flexible panel 120 in a bent state, a rear chassis 230 affixed to a support rib 212 of the support mold 210 by a fixing screw 240, and the like. Referring back to FIG. 1B, the stop protrusion 111 formed as one frame with the support mold 110 is configured to work as a stopper for supporting the edge of the flexible panel 120 from being released. As seen in FIGS. 3A and 3B, a stop bracket 250 may be fastened to the support mold 210 by a screw 251 and may be configured to work as the stopper as shown in FIG. 3C. Stop brackets 250 may be disposed at the four corner portions of the edge of the flexible panel 120 in accordance with the stop protrusions 111.

The display apparatus may be manufactured as shown in FIG. 3B. The flexible panel 120 may be pushed into an accommodation space 210a of the support mold 210 in a bent state, and stop brackets 250 may be fastened to the four corners. Also, the flexible panel 120 may be pushed into the accommodation space 210a after the stop bracket 250s are fastened to the support mold 210, as described with reference to FIGS. 2A, 2B, 2C, 2D, and 2E. In this manner, the stopper may be formed with the stop bracket 250 affixed to a support rib 212 of the support mold 210 compared to the stop protrusion 111.

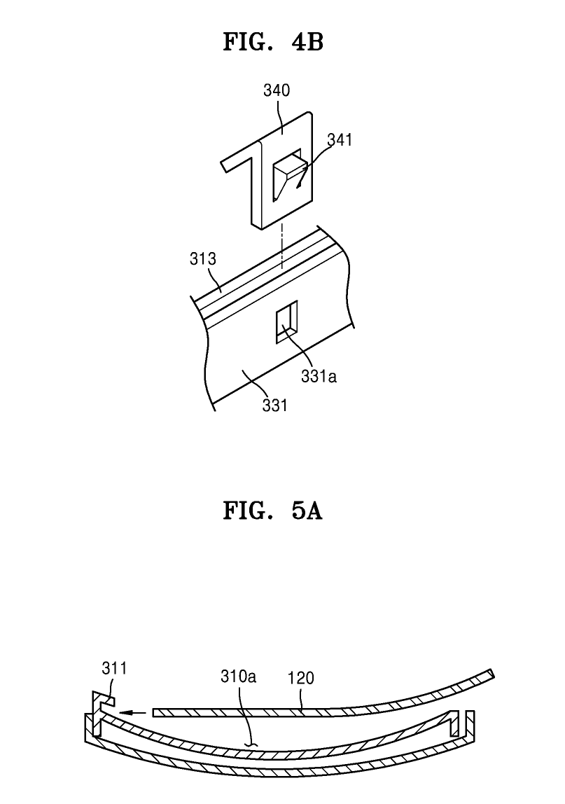

FIGS. 4A and 4B illustrate a display apparatus according to exemplary embodiments.

The display apparatus may include a support mold 310 for supporting the flexible panel 120 in a bent state and a rear chassis 330 coupled to the support mold 310. A stopper for supporting the edge of the flexible panel 120 from being released may include a stop protrusion 311 formed as one body with the support mold 310 and a hook bracket 340 having a locking hook 341. The locking hook 341 may be elastically hooked in a locking hole 331a formed in a side wall 331 of the rear chassis 330. The hook bracket 340 may be locked to the side wall 331 of the rear chassis 330 by inserting the hook bracket 340 between a side wall 313 connected to a support rib 312 of the support mold 310 and the side wall 331 of the rear chassis 330 in which the locking hole 331a is formed. One of the hook bracket 340 and the stop protrusion 311 are disposed at the four corners of the flexible panel 120. For instance, stop protrusions 311 may be disposed at opposing sides from hook brackets 340.

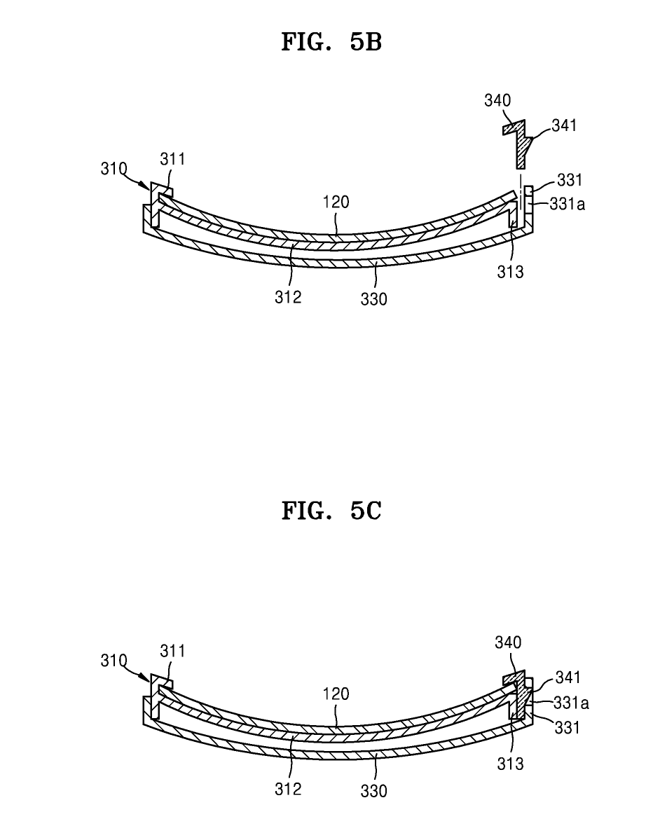

When the display apparatus is manufactured, the flexible panel 120 is inserted into an accommodation space 310a such that one side of the flexible panel 120 is below the stop protrusion 311 as shown in FIG. 5A. Thereafter, the hook bracket 340 is mounted so as to cover the other side of the flexible panel 120 as shown in FIG. 5B. Also, the hook bracket 340 may be coupled to the rear chassis 330, and the flexible panel 120 may be pushed into the accommodation space 310a from the front side as described with reference to FIGS. 2A, 2B, 2C, 2D, and 2E.

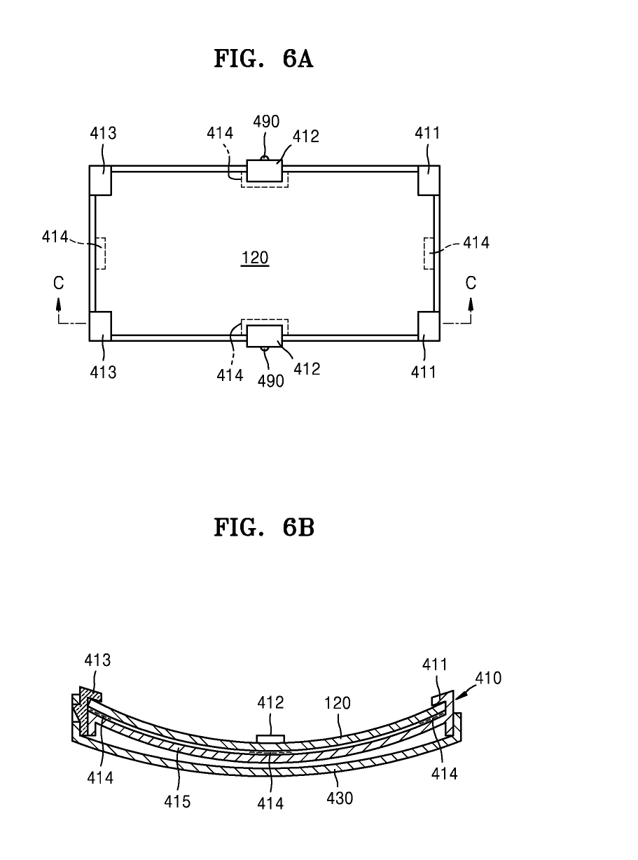

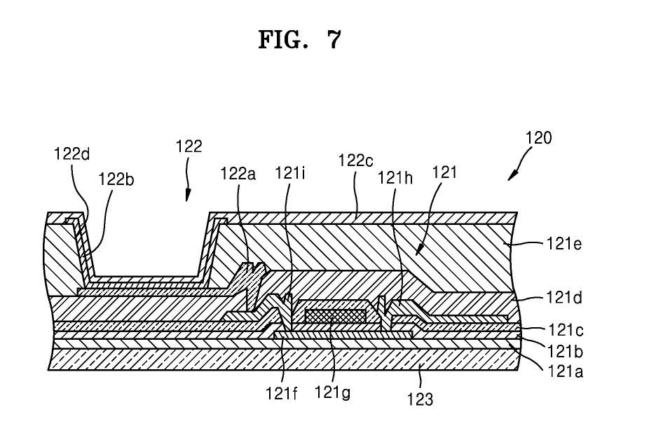

FIGS. 6A and 6B illustrate a display apparatus according to exemplary embodiments;

The display apparatus may include a support mold 410 for supporting the flexible panel 120 in a bent state and a rear chassis 430 coupled to the support mold 410. A stopper for supporting (or otherwise restraining) the edge of the flexible panel 120 from being released may include at least one of a stop protrusion 411 formed as one body with the support mold 410, a hook bracket 413 coupled to the rear chassis 430, and a stop bracket 412 fastened to the support mold 410 using, for example, a screw 490. For instance, the display apparatus may include each of the stop protrusion 411, the hook bracket 413, and the stop bracket 412. Double-sided tape 414 may be disposed between a support rib 415 of the support mold 410 and the flexible panel 120. In this manner, release of the flexible panel 120 may be further restrained by the provided stop bracket 412 and the double-sided tape 414.

As described above, according to exemplary embodiments, since the release of a panel may be stably prevented without a separate front chassis, a display apparatus having a simple structure and which is lightweight and thin may be achieved.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A display apparatus comprising:
a flexible display panel; and
a support mold comprising an opening to an accommodation space,
wherein a width of the accommodation space is smaller than a width of the flexible display panel, and
wherein the support mold is configured to support the flexible display panel in a bent state in the accommodation space.

2. The display apparatus of claim 1, wherein, in the bent state, the flexible display panel is concavely bent with respect to the opening.

3. The display apparatus of claim 2, further comprising:
a stopper configured to restrain the flexible display panel in the accommodation space.

4. The display apparatus of claim 3, wherein the stopper is configured to engage an edge of the flexible display panel.

5. The display apparatus of claim 4, wherein the stopper comprises a stop protrusion protruding from the support mold.

6. The display apparatus of claim 4, wherein the stopper comprises a stop bracket fastened to the support mold.

7. The display apparatus of claim 4, further comprising:
a rear chassis coupled to the support mold, the support mold being disposed between the flexible display panel and the rear chassis,
wherein the stopper comprises a hook bracket comprising a locking hook detachably coupled to a locking hole of the rear chassis.

8. The display apparatus of claim 2, further comprising:
a rear chassis coupled to the support mold, the support mold being disposed between the flexible display panel and the rear chassis.

9. The display apparatus of claim 8, wherein the rear chassis is bent in a same direction as the flexible display panel.

10. The display apparatus of claim 9,
wherein:
the support mold comprises a support rib;
the support rib is disposed between the flexible display panel and the rear chassis;
the support rib is elastically bendable; and
the rear chassis is coupled to the support rib.

11. The display apparatus of claim 2, wherein the support mold comprises an elastically deformable material.

12. A method of manufacturing a display apparatus, the method comprising:
forming a flexible display panel;
forming a support mold comprising an opening to an accommodation space, a width of the accommodation space being less than a width of the flexible display panel; and
inserting the flexible display panel into the accommodation space,
wherein, with respect to the opening, the flexible display panel is concavely bent in the accommodation space.

13. The method of claim 12, wherein:
inserting the flexible display panel into the accommodation space comprises:
pushing, in a first direction, the flexible display panel through the opening;
bending, in the first direction, a support rib of the support mold together with the flexible display panel as the flexible display panel is pushed through the opening and into the accommodation space; and
enabling at least partial bending recovery by the support rib;
the support mold comprises a stop protrusion formed as one body with the support mold; and
the stop protrusion is configured to restrain an edge of the flexible display panel to prevent the flexible display panel from exiting the opening.

14. The method of claim 13, further comprising:
mounting a rear chassis to the support mold, the support mold being disposed between the rear chassis and the flexible display panel; and
coupling the rear chassis to the support rib.

15. The method of claim 12, wherein:
inserting the flexible display panel in the accommodation space comprises:
disposing the flexible display panel into the accommodation space; and
coupling a stop bracket to the support mold at a side of the accommodation space,
wherein the stop bracket is configured to restrain an edge of the flexible display panel from exiting the opening.

16. The method of claim 12, further comprising:
mounting, to the support mold, a rear chassis comprising a locking hole, the support mold being disposed between the rear chassis and the flexible display panel,
wherein inserting the flexible display panel into the accommodation space comprises:
inserting the flexible display panel into a first side of the accommodation space; and
coupling a hook bracket to the support mold at a second side of the accommodation space, the hook bracket comprising a locking hook, configured to detachably engage the locking hole of the rear chassis, and
wherein the hook bracket is configured to restrain an edge of the flexible display panel from exiting the opening.

17. The display apparatus of claim 10, further comprising:
an adhesive coupling the support rib to the flexible display panel.

18. The display apparatus of claim 10, wherein a central region of the support rib
comprises an opening.

19. The display apparatus of claim 3, wherein:
the stopper is one of a plurality of stoppers configured to restrain the flexible display panel in the accommodation space;
the opening is formed between the plurality of stoppers; and
a width of the opening is smaller than a width of the accommodation space.

20. The display apparatus of claim 7, wherein the hook bracket is disposed between a side wall of the support mold and a side wall of the rear chassis.
